(19) United States
(12) Patent Application Publication
(10) Pub. No.: US 2013/0015311 A1
(43) Pub. Date: Jan. 17, 2013

(54) SLIM-TYPE QUICK CRADLE FOR A PORTABLE TERMINAL

(71) Applicant: Ji-Hyun KIM, Gyeonggi-do (KR)

(72) Inventor: Ji-Hyun KIM, Gyeonggi-do (KR)

(73) Assignee: SAMSUNG ELECTRONICS CO., LTD., Gyeonggi-do (KR)

(21) Appl. No.: 13/545,069

(22) Filed: Jul. 10, 2012

(30) Foreign Application Priority Data
Jul. 13, 2011 (KR) 10-2011-0069246

(51) Int. Cl. H05K 7/00

(52) U.S. Cl. 248/393

(57) ABSTRACT

A slim-type quick cradle for a portable terminal is provided, in which a support bar inclinedly supports the portable terminal, an engagement frame secures the support bar on a bottom surface of a body, and a hinge device connects the support bar with the engagement frame rotatably around a hinge axis and provides a closing, opening or stopping force to the support bar semi-automatically.

### CLAIM OF PRIORITY

This application claims priority under 35 U.S.C. §119 to a Korean Patent Application filed in the Korean Intellectual Property Office on Jul. 13, 2011 and assigned Ser. No. 10-2011-0069246, the contents of which are incorporated herein by reference.

### BACKGROUND OF THE INVENTION

1. Field of the Invention

The present invention relates to a portable terminal, and more particularly, to a slim-type quick cradle for facilitating inclined cradling of the portable terminal

2. Description of the Related Art

A portable terminal typically refers to a cellular phone, a smart phone, a smart pad, an electronic book, etc.

In operation, the portable terminal displays data on a screen, and a user can view in a variety of modes, such as a Digital Multimedia Broadcasting (DMB) mode, a TV mode, or a Video On Demand (VOD) mode,

However, as a user holds the terminal during program, the holding posture can cause fatigue to hands and arms during replay.

Alternatively, the user may view the screen, while cradling the portable terminal to be inclined on a portable cradle. However, it is inconvenient to carry the portable cradle around all the time, and the provision of a portable cradle adds to the volume to the portable terminal which in turn is a drawback in portability of the portable terminal.

### SUMMARY OF THE INVENTION

An aspect of embodiments of the present invention is to address at least the problems and/or disadvantages and to provide at least the advantages described below. Accordingly, an aspect of embodiments of the present invention is to provide a slim-type quick cradle which is slim in overall appearance and semi-automatically operated so that the slim-type quick cradle is opened or closed fast and easily for cradling a portable terminal, thus enabling a user to comfortably view a screen on the portable terminal in Digital Multimedia Broadcasting (DMB) mode, Video On Demand (VOD) mode, and TV mode, conveniently for a long time, keeping the right posture.

In accordance with an embodiment of the present invention, there is provided a slim-type quick cradle for a portable terminal, in which a support bar inclinedly supports the portable terminal, an engagement frame secures the support bar on a bottom surface of a body, and a hinge device connects the support bar with the engagement frame rotatably around a hinge axis and provides a closing, opening or stopping force to the support bar semi-automatically.

In accordance with another embodiment of the present invention, there is provided a slim-type quick cradle for a portable terminal, in which a support bars a pair of support walls integrally, one of the support walls having a locking groove formed along a direction of a hinge axis and inclinedly supports the portable terminal, an engagement frame has a pair of support arms engaged with the pair of support walls and a separation wall between the support arms and secures the support bar on a bottom surface of a body, and a hinge device has a driving cam which includes a locking protrusion engaged with the locking groove and rotates together with the support bar, fixed to one of the support walls, and a cam follower for making a cam motion in close contact with the driving cam, and connects the support bar with the engagement frame with respect to the hinge axis.

### BRIEF DESCRIPTION OF THE DRAWINGS

The above features and advantages of certain embodiments of the present invention will be more apparent from the following detailed description taken in conjunction with the accompanying drawings, in which:

FIG. 1 is a side view of a portable terminal having a cradle in a rotated state according to the present invention;

FIG. 2 is a perspective view of the portable terminal supported by the cradle according to the present invention;

FIG. 3 is a frontal view of the portable terminal having the cradle according to the present invention;

FIG. 4 is a frontal view of the cradle according to the present invention;

FIG. 5 is a perspective view of the cradle with an elastic member eliminated in a closed state according to the present invention;

FIG. 6 is a perspective view of the cradle in a fully open state according to the present invention; and

FIG. 7 is a perspective view of a driving cam locked to a support wall in the cradle according to the present invention.

Throughout the drawings, the same drawing reference numerals will be understood to refer to the same elements, features and structures.

### DETAILED DESCRIPTION

Reference will now be made in detail to the preferred embodiments of the present invention with reference to the accompanying drawings. Like reference numerals denote the same components in the drawings.

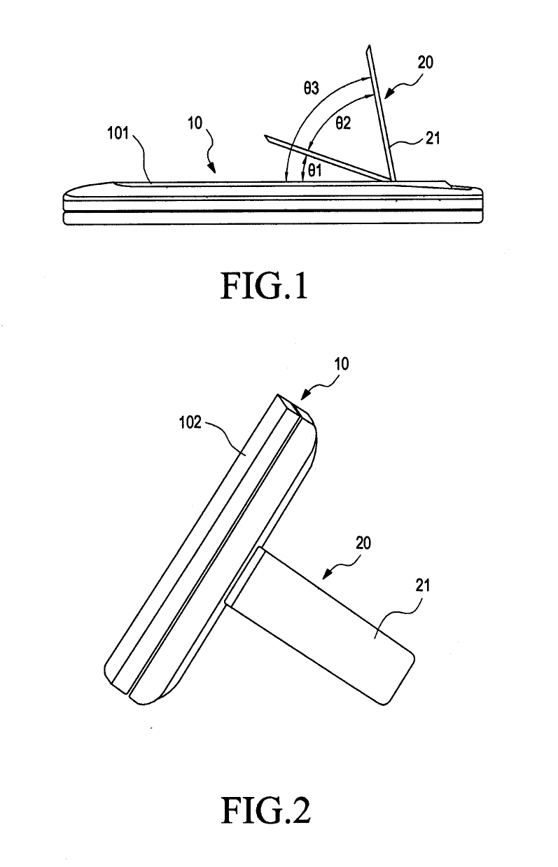

FIGS. 1, 2 and 3 illustrate a portable terminal having a slim-type quick cradle 20 (hereinafter, shortly referred to as a cradle 20 according to the present invention.

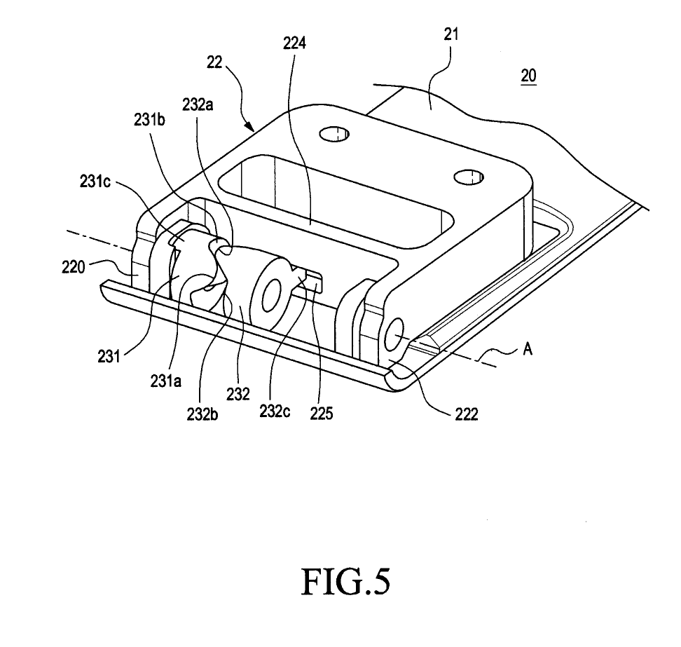

Referring to FIG. 1, the cradle 20 includes a later-described hinge device (23 in FIGS. 4 and 5) that is configured so as to provide a force to close the cradle 20 to a bottom surface 101 of a body 10 of the portable terminal at or below a first angle Θ1, to provide an opening force to the cradle 20 at an angle between the first angle Θ1 and a second angle Θ2, and to provide a stopping force to the cradle 20 at a third angle Θ3=Θ1+Θ2.

As a result, a user can use the cradle 20 fast and easily according to the above design scheme.

The cradle 20 is disposed at a predetermined position of the bottom surface 101 of the body 10, along a length direction of the bottom surface 101 by means of the later-described hinge device.

When a support bar 21 of the cradle 20 having the above-described configuration rotates up to the third angle Θ3, the support bar 21 is kept stationary. The stopping force is provided by the later-described hinge device. FIG. 2 illustrates a top view of the body 10 of the portable terminal cradled inclinedly on the cradle 20.

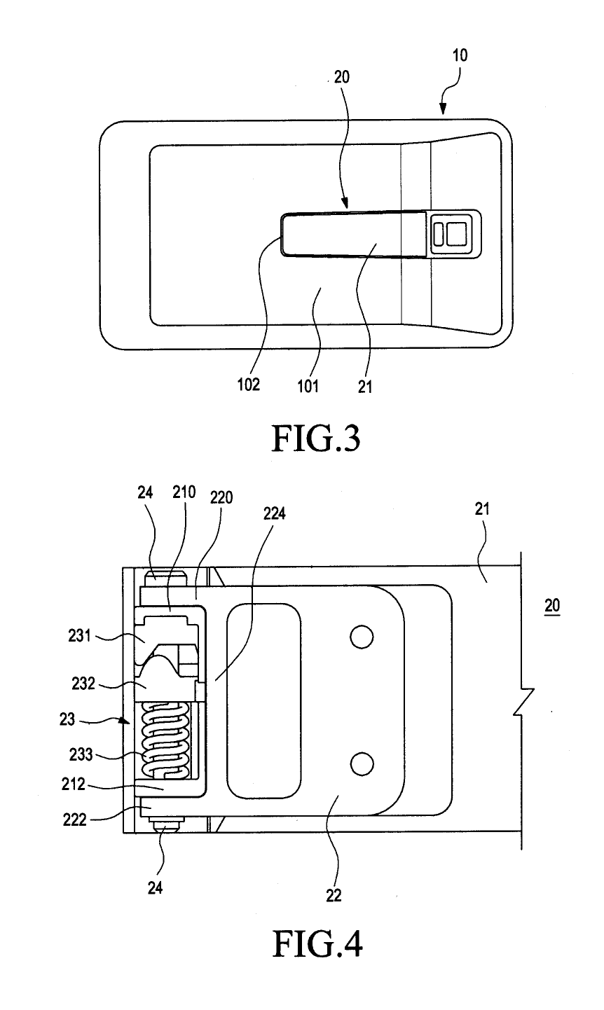

The cradle 20 is configured so that the support bar 21 is forcedly rotated up to the first angle from a recess (102 in FIG. 3) formed at a predetermined position of the bottom surface 101 of the body 10. Once the support bar 21 exceeds the first angle Θ1, it is automatically opened to the second angle Θ2. That is, the support bar 21 of the cradle 20 is manually opened to 0° to the first rotation angle Θ1 and thereafter automatically opened to the first rotation angle Θ1 to the second rotation angle Θ2. Thus, the cradle 20 is semi-automatically opened and closed.

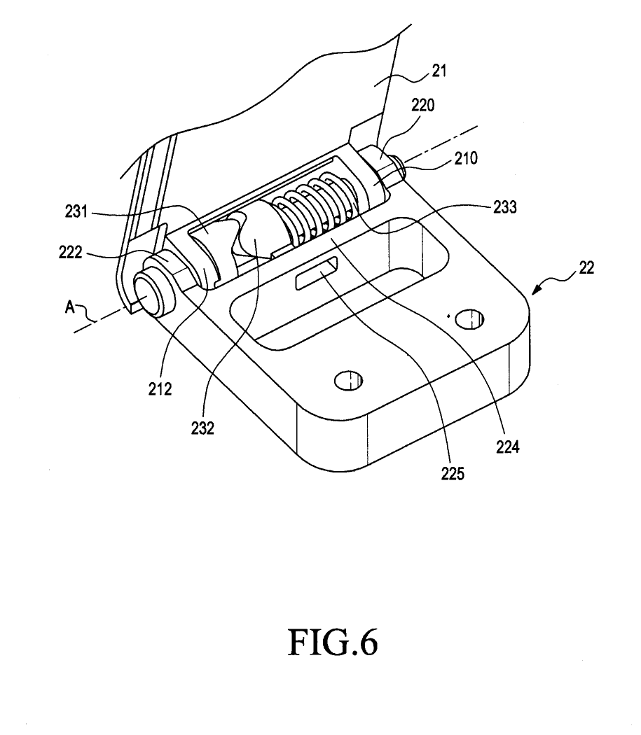

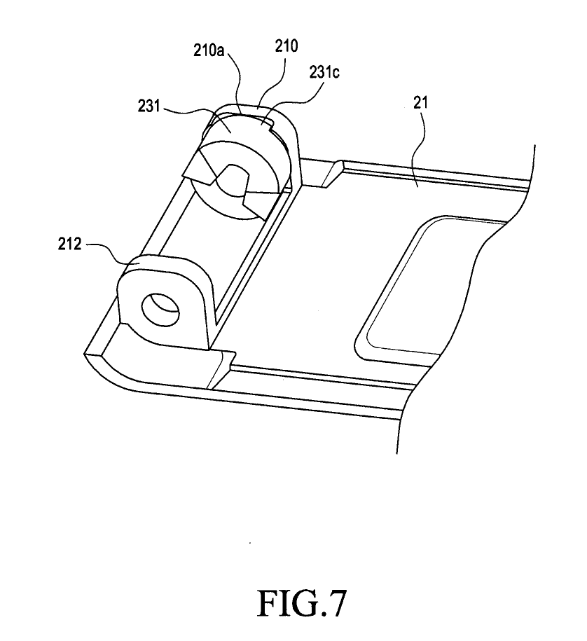

Hereinafter, with reference to FIGS. 4 to 7, the configuration of the cradle 20 will be described in detail.

Referring to FIGS. 4, 5 and 6, the cradle 20 is a slim-type quick cradle and includes the support bar 21, an engagement frame 22, and the hinge device 23. The support bar 21 is rotated and thus inclinedly supports the body (10 in FIGS. 1 and 2) of the portable terminal The engagement frame 22 secures the cradle 20, particularly the support bar 21 and the hinge device 23 in the bottom surface 101 of the body. The hinge device 23 provides a closing, opening, or stopping force to the support bar 21, while connecting the support bar 21 to the engagement frame 22.

The support bar 21 includes two support walls 210 and 212 in an end area, for accommodating a cam unit 231 and 232 and an elastic member 233 along a hinge axis A1. The support walls 210 and 212 face each other, with the cam unit 231 and 231 and the elastic member 233 interposed along a hinge shaft 24 between the support walls 210 and 212. An opening is formed on each of the support walls 210 and 212, for allowing the hinge shaft 24 to be inserted thereinto. When the cradle 20 is mounted onto the bottom surface of the body 10 of the portable terminal with the cam unit 231 and 232 and the elastic member 233 accommodated in the space between the pair of support walls 210 and 212, the cradle 20 is accommodated into the body 10 of the portable terminal. The support bar 21 has an inner surface facing the bottom surface 101 of the body 10 and an outer surface exposed from the bottom surface 101 of the body 10.

The engagement frame 22 is engaged with a fastener (not shown) in a predetermined area of the bottom surface 101 of the body 10 by means of the hinge device 23. As the engagement frame 22 is engaged with the predetermined area of the bottom surface 101 of the body 10, the support bar 21 rotates integrally and engages with the bottom surface 101 of the body 10 by means of the hinge device 23 and the engagement frame 22. The engagement frame 22 includes two engagement arms 220 and 222 and a separation wall 224. The engagement arms 220 and 222 and the separation wall 224 surround the support walls 210 and 212, the cam unit 231 and 232, and the elastic member 233.

The engagement arms 220 and 222 are linearly extended from both corners of a body of the engagement frame 22, facing the support walls 210 and 212, respectively, for allowing the hinge shaft 24 to penetrate therethrough. To allow the hinge shaft 24 to penetrate through the engagement arms 220 and 222, the engagement arms 220 and 222 have openings. The separation wall 224 is extended perpendicularly to the direction in which the engagement arms 220 and 222 are extended, that is, along the direction of the hinge axis A. A guide hole 225 is formed into the separation wall 224 to allow the cam follower 232 to linearly move along the direction of the hinge axis A. The guide wall 225 is elongated in parallel to the hinge axis A. As a cam protrusion (232c in FIG. 5) of the cam follower 232 is inserted into the guide hole 225, the cam follower 232 may move linearly along the direction of the hinge axis A, along with a rotation of the later-described driving cam 231. That is, the guide hole 225 prevents rotation of the cam follower 232 and guides a reciprocal movement of the cam follower 232 along the direction of the hinge axis A.

The hinge device 23 includes the hinge shaft 24, the cam unit 231, the cam follower 232, and the elastic member 233. The hinge shaft 24 provides the hinge axis A of the hinge device 23, penetrating through the cam unit 231, and the cam follower 232 and the elastic member 233. The driving cam 231 refers to a cam that rotates together with the support bar 21, and the cam follower 232 refers to a cam that moves linearly along the hinge axis by a cam motion along with rotation of the driving cam 231.

The driving cam 231 is provided with a cam means at one side surface and a locking means at the other side surface. Specifically, the driving cam 231 is provided, on one side surface thereof, with a cam groove 231b and a cam protrusion 231a, for creating a cam motion, and on the other side surface thereof, with a locking protrusion 231c for locking the driving cam 231. The locking protrusion 231c is inserted into a locking groove 210a formed into the support wall 210 of the support bar 21, thus making the driving cam 231 rotate together with the support bar 21. That is, the driving cam 231 rotates together with the support bar 21 through an engagement between the locking protrusion 231c and the locking groove 210a.

The cam follower 232 includes a cam grove 232b and a cam protrusion 232a. The cam follower 232 further includes a guide protrusion 232c on its outer circumferential surface. Thus, the cam follower 232 makes a linear reciprocal motion along the guide hole 225, along with a rotation of the driving cam 231.

The elastic member 233 provides a force that brings the driving cam 231 and the cam follower 232 into a close contact and thus enables the driving cam 231 and the cam follower 232 to make a cam motion. The elastic member 233 is preferably a compressed coil spring. As the driving cam 231 rotates, the elastic member 2322 is pressed or pulled along the hinge axis A.

In the above configuration of the cradle 20, the cam unit 231, the cam follower 232 and the elastic member 233 are fully accommodated in the engagement frame 22, which is disposed in parallel with its part being accommodated in the support bar 21. This configuration contributes to slimming of the cradle 20. Especially, the support bar 21 can be fast opened or closed semi-automatically by the hinge device 23.

As is apparent from the above description, the cradle according to the present invention is slim in overall appearance and is fast opened and closed. As the cradle is operated semi-automatically, the user convenience is increased as it enables the user to comfortably view a screen on a portable terminal put on a table in any of DM mode, VOD mode, and TV mode. Especially, since the cradle is made slim, it can be integrally disposed on the bottom surface of the body of the portable terminal, and the semi-automatic opening and closing of the cradle improves the operation convenience. Therefore, the user can view a screen on the portable terminal for a long time while maintaining the right posture.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. A slim-type quick cradle for a portable terminal, comprising:
a support bar for inclinedly supporting the portable terminal;
an engagement frame for securing the support bar on a bottom surface of a body; and
a hinge device for coupling the support bar with the engagement frame rotatably around a hinge axis and providing a closing, opening or stopping force to the support bar semi-automatically.

2. The slim-type quick cradle of claim 1, wherein when a rotation of the support bar exceeds a first angle, the hinge device enables to the support bar to rotate semi-automatically to a second angle.

3. The slim-type quick cradle of claim 2, wherein the support bar is rotated manually up to the first angle.

4. The slim-type quick cradle of claim 1, wherein the support bar integrally includes a pair of support walls for accommodating the hinge device.

5. The slim-type quick cradle of claim 2, wherein the hinge device includes a driving cam and a cam follower, and
wherein the driving cam is fixed to one of the support walls to enable the driving cam to rotate together with the support bar.

6. The slim-type quick cradle of claim 5, wherein the one support wall includes a locking groove recessed along a direction of the hinge axis, and the driving cam includes a locking protrusion extended along the direction of the hinge axis and engaged into the locking groove.

7. The slim-type quick cradle of claim 5, wherein the engagement frame includes a pair of support arms engaged with the support walls and a separation wall between the support arms, and wherein the separation wall includes a guide opening for guiding linear movement of the cam follower.

8. A slim-type quick cradle for a portable terminal, comprising:
a support bar having a pair of support walls integrally, one of the support walls having a locking groove recessed along a direction of a hinge axis, for inclinedly supporting the portable terminal;
an engagement frame having a pair of support arms engaged with the pair of support walls and a separation wall between the support arms, for securing the support bar on a bottom surface of a body; and
a hinge device having a driving cam which includes a locking protrusion engaged with the locking groove and rotates together with the support bar, fixed to one of the support walls, and a cam follower for making a cam motion in close contact with the driving cam, for connecting the support bar with the engagement frame with respect to the hinge axis.

9. The slim-type quick cradle of claim 8, the separation wall includes a guide opening for guiding linear movement of the cam follower.

10. The slim-type quick cradle of claim 6, wherein the locking protrusion is extended from the other surface of the driving cam along the direction of the hinge axis.

11. The slim-type quick cradle of claim 8, wherein when a rotation of the support bar exceeds a first angle, the hinge device enables to the support bar to rotate semi-automatically to a second angle.

12. The slim-type quick cradle of claim 11, wherein the support bar is rotated manually up to the first angle.
